(19) United States
(12) Patent Application Publication
(10) Pub. No.: US 2011/0026295 A1
(43) Pub. Date: Feb. 3, 2011

(54) SEMICONDUCTOR MEMORY

(75) Inventor: Yoshinori MATSUI, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/898,123

(22) Filed: Oct. 5, 2010

Related U.S. Application Data
(62) Division of application No. 12/149,856, filed on May 9, 2008.

(30) Foreign Application Priority Data
May 30, 2007 (JP) 2007-143142

(51) Int. Cl. G11C 5/06; G11C 29/00

(52) U.S. Cl. 365/63

(57) ABSTRACT

To arrange data input/output PADs of a semiconductor memory on a narrower pitch without enhancing a required positional accuracy for a probe in a probe check. A semiconductor memory includes: a memory cell array including memory cells; signal terminals; a power source terminal of a power source supplied to output circuits of the signal terminals; test-purpose signal terminals fewer than the signal terminals; a selection portion which, as data to be written to the memory cells, selects data input from the signal terminals or data input from the test-purpose signal terminals, and repetitively allocates inputs of the test-purpose signal terminals to inputs of the signal terminals based on an arrangement of the signal terminals; and a test-purpose power source terminal connected to the power source terminal, and arrangement intervals of the test-purpose signal terminals and the test-purpose power source terminal are larger than an arrangement interval of the signal terminals.

### CROSS-REFERENCE TO RELATED PATENT APPLICATIONS

This application is a divisional of application Ser. No. 12/149,856, filed May 9, 2008, now pending, which claims the benefit of priority from the prior Japanese Patent Application No. 2007-143142, filed May 30, 2007, the entire contents of which are incorporated herein by reference. This application claims only subject matter disclosed in the parent application and therefore presents no new matter.

### BACKGROUND OF THE INVENTION

1. Field of the Invention

The present invention relates to a semiconductor memory for preferable use when stacked with a processor chip and the like in the same package.

2. Description of Related Art

In recent years, demands for downsized portable equipment have prompted development of systems in which a semiconductor memory and a processor chip or the like are stacked in the same package (for example, see Japanese Unexamined Patent Publication, First Publication No. 2006-177911). In such systems, terminals for the signals exchanged between the chips are directly connected by wires in order to mount the chips in a smaller package. Direct connection between the chips has advantages such as that the chip-to-chip signal delay is reduced to facilitate high-speed signal transmission, and that the signal load is reduced to reduce power consumption by the system.

Furthermore, to increase the data transfer rate for enhancing the performance of the system, the number of data input/output terminals between the semiconductor memory and the processor has a tendency to expand, for example, from 32 to 64. That is, the chip size is decreasing to be mounted in a small-size package while the number of terminals is increasing. As a result, to reduce the overhead on the chip layout, PADs for wire-bonding are required to be smaller and arranged on a narrower pitch.

In recent years, improvement on the accuracy of wire-bonding for PADs has enabled wire-bonding for PADs arranged on a narrow pitch of 60 micrometers or less.

At the time of a shipment test of a semiconductor memory, it is necessary to make a check of these PADs by probing signal terminals from a memory tester. For a semiconductor memory, a long test time is needed because a test of high capacitance memory cells is made, and the probe check is conducted by simultaneously probing a multitude (100 to 200) of chips. A probing apparatus for conducting such a test has 20,000 to 40,000 probe needles. High positional accuracy is required for the tips of all the probes. However, improvement in the positional accuracy of the probe tips is less advanced than the improvement in accuracy of wire bonding. The probe tips for general use in mass production of semiconductor memories have a pitch of approximately 80 micrometers.

In the case of a processor chip, the test time is short and the necessity to test for simultaneously probing a multitude of chips is low. Therefore, the number of probe needles for a probing apparatus is small compared with the case of a semiconductor memory. Consequently, in a processor chip, high positional accuracy is available, and probing is available even with a pitch of 60 micrometers or less, which is an accuracy equivalent to that of wire bonding.

To realize the above-mentioned high performance system in which a semiconductor memory and a processor chip are stacked in the same package, it is required that the PADs on the semiconductor memory side also be arranged with a pitch of 60 micrometers or less, which is the same pitch for those of the processor chip, because both chips are directly connected to each other with wires, as described above. However, arranging the PADs on the semiconductor memory side with a pitch of 60 micrometers or less presents a problem in that a probe check at the time of a shipment test becomes difficult.

### SUMMARY OF THE INVENTION

The present invention has been achieved in view of such a problem, and has an object to provide a semiconductor memory in which PADs of data input/output terminals can be arranged on a narrower pitch without enhancing the required positional accuracy for a probe in a probe check, compared with conventional cases.

A semiconductor memory of the present invention includes: a memory cell array which includes a plurality of memory cells; a plurality of signal terminals; a power source terminal of a power source supplied to output circuits of the signal terminals; a plurality of test-purpose signal terminals fewer than the signal terminals; a selection portion which, as data to be written to the memory cells, selects data having been input from the signal terminals or data having been input from the test-purpose signal terminals, and repetitively allocates inputs of the respective test-purpose signal terminals to inputs of the respective signal terminals based on an arrangement of the signal terminals on a memory chip; and a test-purpose power source terminal which is connected to the power source terminal, wherein arrangement intervals of the test-purpose signal terminals and the test-purpose power source terminal are larger than an arrangement interval of the signal terminals.

With the above configuration, either data having been input from the signal terminals such as data input/output DQ terminals and data strobe input/output DQS terminals or data having been input from the test-purpose signal terminals is selected as data to be written to memory cells, and inputs of the respective test-purpose signal terminals are repetitively allocated to inputs of the respective signal terminals based on an arrangement of the respective signal terminals on a memory chip, to thereby make an arrangement interval of the test-purpose signal terminals and make the test-purpose power source terminal larger than that of the signal terminals. As a result, predetermined data is input from the test-purpose signal terminals to be written to the memory cells, and then the written data is read, to thereby control the respective output circuits to ON or OFF, or control a plurality output circuits alternately to ON or OFF. Consequently, a leak test can be conducted using the test-purpose signal terminals and the test-purpose power source terminal. Therefore, a leak test can be conducted without probing in the signal terminals, making it possible to make a pitch between the terminals (PADs) such as data input/output DQ terminals and data strobe input/output DQS terminals narrow enough, for example to meet the requirement when the semiconductor memory is stacked with a processor chip.

A semiconductor memory of the present invention includes: a memory cell array which includes a plurality of memory cells; a plurality of signal terminals; a plurality of test-purpose signal terminals fewer than the signal terminals; a selection portion which, as data to be written to the memory cells, selects data having been input from the signal terminals or data having been input from the test-purpose signal terminals, and repetitively allocates inputs of the respective test-purpose signal terminals to inputs of the respective signal terminals based on an arrangement of the signal terminals on a memory chip; a plurality of comparison portions which compares data which has been read from the memory cells with outputs of output circuits from which the read data is output; a combination portion which combines comparison results by the plurality of comparison portions; and an output portion which outputs a combination result by the combination portion from any of the test-purpose signal terminals, wherein an arrangement interval of the test-purpose signal terminals is larger than an arrangement interval of the signal terminals.

With the above configuration, data having been read from the memory cells and outputs of output circuits to which the read data is output are compared, and the comparison results are combined. Then, the combined result is output from any of the test-purpose signal terminals. As a result, an operation check test can be conducted on output circuits of the signal terminals without probing in the signal terminals.

Preferably, the semiconductor memory further includes: an output circuit equivalent to the output circuits of the signal terminals provided in an input signal terminal; and a control portion which controls the equivalent output circuit similarly to a further adjacent output circuit based on an arrangement of the signal terminals on the memory chip.

With the above configuration, an output circuit which is equivalent (equivalent in input capacitance) to an output circuit of a signal terminal provided in an input signal terminal is provided, and the equivalent output circuit is controlled in a similar manner for a further adjacent output circuit based on an arrangement of the respective signal terminals on a memory chip. As a result, a leak test can also be conducted on an input signal terminal in a similar manner for a signal terminal provided with an output circuit.

Preferably, in the semiconductor memory, the input signal terminal is an input terminal for a data mask signal.

With the above configuration, even in a semiconductor memory provided with an input terminal for a data mask signal, PADs of data input/output terminals of a semiconductor memory can be arranged on a narrower pitch without enhancing the required positional accuracy for a probe.

### BRIEF DESCRIPTION OF THE DRAWINGS

FIG. 1 shows a chip layout of a semiconductor memory as a background art of the present invention.

FIG. 2 is a block diagram of the semiconductor memory chip shown in FIG. 1.

FIG. 3 is a timing chart at the time of a basic operation of the semiconductor memory shown in FIG. 1.

FIG. 4 shows a chip layout of a semiconductor memory in accordance with an embodiment of the present invention.

FIG. 5 is a block diagram of the semiconductor memory chip shown in FIG. 4.

FIG. 6 shows an exemplary configuration of a data latch circuit 405 shown in FIG. 5.

FIG. 7 is a timing chart at the time of a leak test of the semiconductor memory shown in FIG. 5.

FIG. 8 is a diagram explaining operations of DQ terminal input/output circuits at the time of a leak test of the semiconductor memory shown in FIG. 5 (at the time of measurement of a VDDQ current).

FIG. 9 is diagram explaining operations of the DQ terminal input/output circuits at the time of a leak test of the semiconductor memory shown in FIG. 5 (at the time of measurement of a VSSQ current).

FIG. 10 is diagram explaining operations of the DQ terminal input/output circuits at the time of a terminal-to-terminal leak test of the semiconductor memory shown in FIG. 5.

FIG. 11 shows one example of a PAD array.

FIG. 12 is a diagram as a background art of the present invention, showing a configuration provided with a transistor for DM terminal capacitance correction.

FIG. 13 shows the configuration of a transistor for DM terminal capacitance correction of the semiconductor memory shown in FIG. 5; and operations of the input/output circuits thereof at the time of a leak test.

FIG. 14 is a timing chart at the time of a leak test on DQ, DQS, and DM terminals shown in FIG. 13.

FIG. 15 is a diagram explaining operations of the input/output circuits at the time of a terminal-to-terminal leak test of DQs and a DM in FIG. 13.

FIG. 16 is a diagram explaining operations of the input/output circuits at the time of a terminal-to-terminal leak test of the DM and a DQS in FIG. 13.

FIG. 17 shows the configuration of an operation check test circuit for input/output circuits of the semiconductor memory in accordance with an embodiment of the present invention.

FIG. 18 shows one example of a data comparison circuit 1607 shown in FIG. 17.

FIG. 19 is a timing chart of an operation test on input/output circuits of DQ, DQS, and DM terminals in the semiconductor memory shown in FIG. 17.

### DETAILED DESCRIPTION OF THE INVENTION

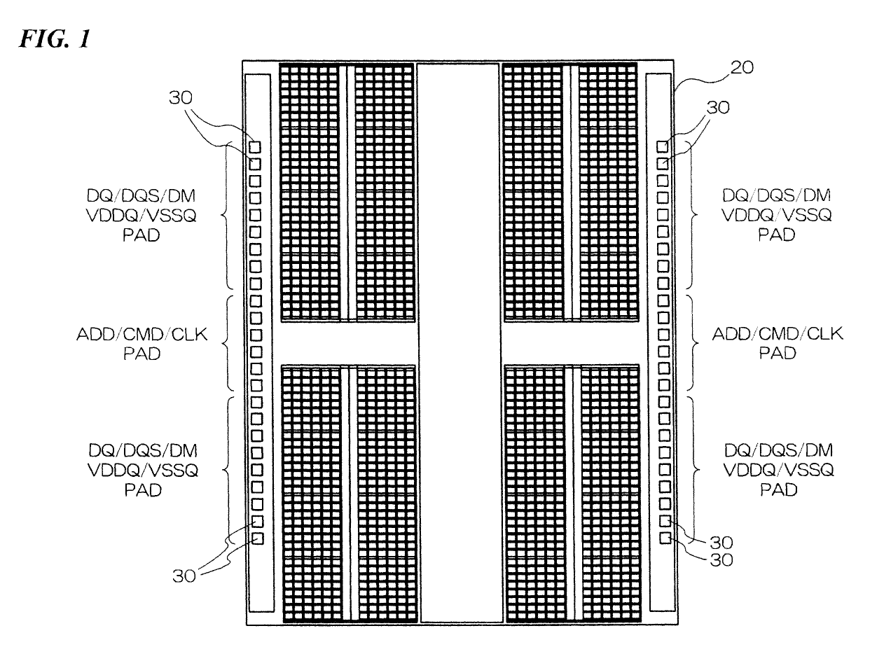

Hereunder is a description of embodiments of a semiconductor memory in accordance with the present invention with reference to the drawings. To make the description of the present invention easy to understand, basic configuration and operations of a semiconductor memory as a background art of the present invention will be first described with reference to FIG. 1 to FIG. 3.

FIG. 1 shows one example of the layout of a semiconductor memory chip as a background art of the present invention. Input/output terminals (input or input/output terminals) of the semiconductor memory chip 20 shown in FIG. 1 (hereinafter, sometimes referred to simply as the semiconductor memory 20) include: a clock signal input CLK; a command signal input CMD; an address signal input ADD; a data signal input/output DQ; a CLK signal input/output DQS for data transmission/reception; and a data mask signal input DM. The semiconductor memory chip 20 functions by connecting PADs 30, 30, . . . of these input/output terminals arranged as shown in FIG. 1 with external terminals by means of wires or the like. Furthermore, at the time of a shipment test, a signal terminal of an external memory tester (not shown in the figure) is probed in these PADs 30, 30, . . . to make a check such as a leak test on the input/output terminals and an operation check test on input/output circuits.

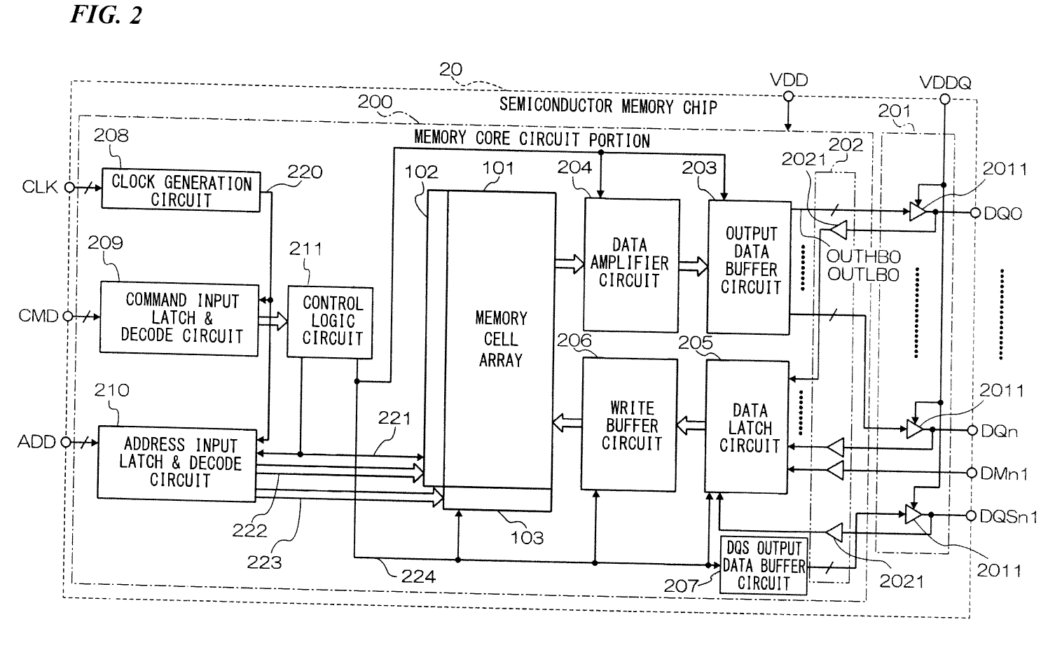

FIG. 2 is a block diagram of the semiconductor memory 20 shown in FIG. 1. The semiconductor memory 20 includes a memory core circuit portion 200 and an output circuit portion 201. A VDD and a VDDQ are power sources to be supplied respectively to the memory core circuit portion 200 and the output circuit portion 201. A semiconductor memory usually has separate power sources. Especially in recent years, when a semiconductor memory is used in portable equipment with low power consumption, a VDDQ with a voltage level lower than a VDD is supplied, to thereby reduce consumption current of the system.

The memory core circuit portion 200 includes: a memory cell array 101 including a plurality of memory cells; a row decoder 102 and a column decoder 103 for selecting a predetermined memory cell within the memory cell array 101; an input circuit 202 including a plurality of buffer circuits 2021; an output data buffer circuit 203; a data amplifier circuit 204; a data latch circuit 205; a write buffer circuit 206; a DQS (differential data strobe) output data buffer circuit 207; a CLK (clock) generation circuit 208; a command input latch & decode circuit 209; an address input latch & decode circuit 210; and a control logic circuit 211. In addition, the output circuit portion 201 includes a plurality of buffer circuits 2011.

Basic operations of the semiconductor memory chip 20 as a background art of the present invention will be described using FIG. 2. A command signal CMD and an address signal ADD are taken respectively into the command input latch & decode circuit 209 and the address input latch & decode circuit 210 by an internal clock signal 220 generated in the CLK generation circuit 208 based on the clock signal CLK input. The command signal CMD is, after decoded in the command input latch & decode circuit 209, input to the control logic circuit 211. The control logic circuit 211 generates a row control signal 221, a column control signal 224, etc. in accordance with the command which has been input, and controls the address input latch & decode circuit 210 which outputs a row address signal 222 and a column address signal 223; the row decoder 102 and the column decoder 103; and respective circuits 201 to 207, to thereby perform the desired operations.

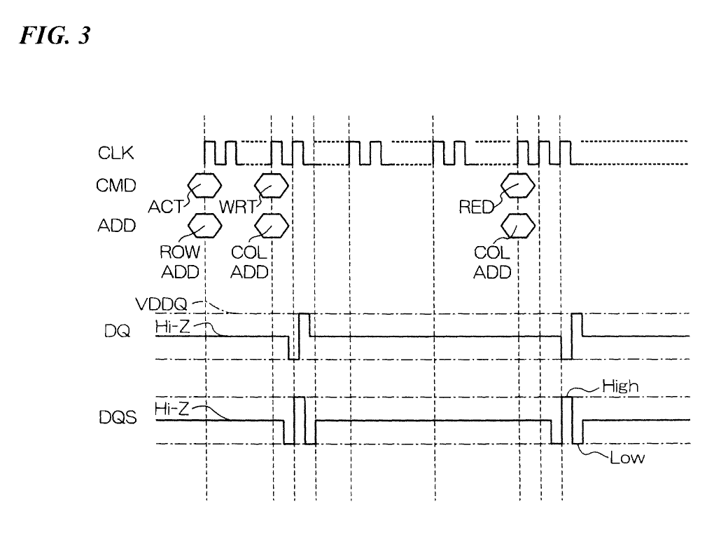

FIG. 3 shows a timing chart when data is written to the semiconductor memory 20 shown in FIG. 1 and FIG. 2 or data is read from the semiconductor memory 20. To write data to or read data from the semiconductor memory 20, it is necessary prior to such operations to input an active command (ACT) to the command signal input CMD to bring the memory cell array 101 into an active state. A row address signal (ROWADD) is input to the address signal input ADD at the same time with the active command (ACT). Thereby, a row address line within the memory cell array 101 is selected to be brought into an active state. Subsequently, when a write command (WRT) is input to the command signal input CMD and at the same time a column address signal (COLADD) is input to the address signal input ADD, data is written to a memory cell at a column address on the row address line based on a signal which has been input from the data input/output DQ.

This timing chart shows an example of the case where writing is performed to two successive bits from a selected column address. Write data DQ (DQ0 to DQn input/output, where n is 0 or a natural number) is received by the input circuit 202, and after taken into the data latch circuit 205 at a rising edge and a falling edge of a CLK signal DQS for data transmission/reception (DQSn1 input, where n1 is 0 or a natural number) which is input synchronous with the next cycle of the cycle in which a write command (WRT) has been input, and is written to a selected memory cell within the memory cell array 101 by the write buffer circuit 206.

Next, when a read command (RED) is input to the command signal input CMD and at the same time a column address signal (COLADD) is input to the address signal input ADD, the data written to the memory cell at the column address on the row address line is read from the memory cell array 101 to the data amplifier circuit 204. The data read to the data amplifier circuit 204 is buffered in the output data buffer circuit 203, and is output from the output circuit portion 201 to the DQ terminals (DQ0 to DQn terminals) synchronous with the cycle after two cycles has elapsed from when the read command (RED) has been input.

This timing chart shows an example of the case where two successive bits are read from a selected column address. At the time of reading, the CLK signal DQS for data transmission/reception is output at a timing leading the DQ output by a half cycle. Output level data of the DQS to be output is sent from the DQS output data buffer circuit 207 to the output circuit portion 201. A high level signal is output at the same time with the first bit of the DQ output, and a low level signal is output at the same time with the second bit thereof.

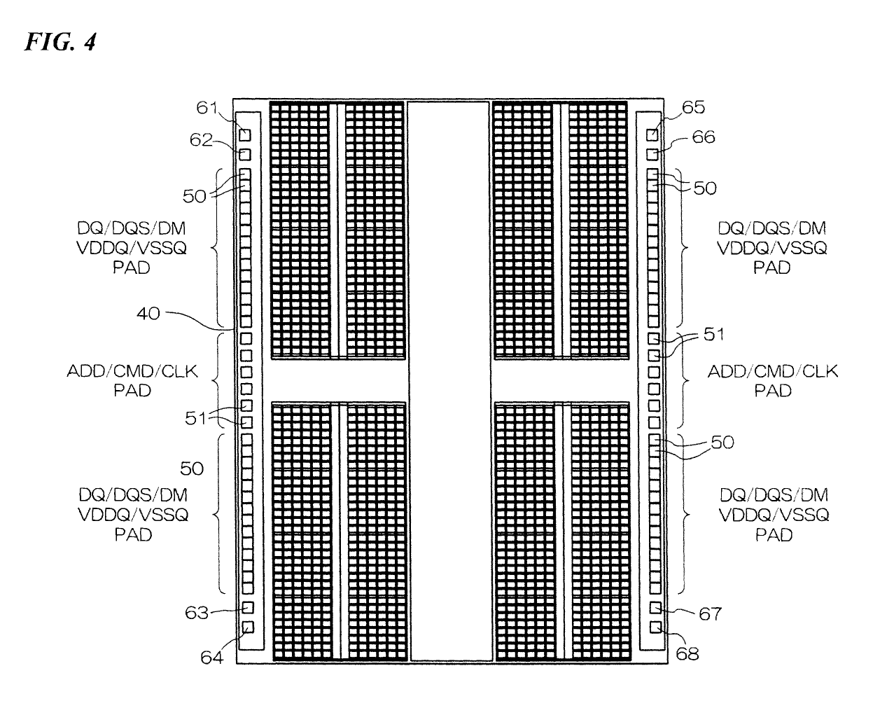

Next is a description of a semiconductor memory in accordance with an embodiment of the present invention. FIG. 4 shows a chip layout of a semiconductor memory 40 in accordance with an embodiment of the present invention. In the present embodiment, the PAD layout is different from that in the chip layout of the semiconductor memory shown in FIG. 1 in the following point. Respective PADs (PADs 50, 50, . . . ) for a DQ (data input/output signal), a DQS (differential data strobe signal), a DM (write data mask signal), and power sources VDDQ and VSSQ, which occupy the majority of all the PADs, are laid out with a narrow pitch (up to 60 micrometers) to fit the pitch of a processor chip in order to make possible a direct connection with the processor chip to be stacked with. On the other hand, respective PADs (PADs 51, 51, . . . ) for an ADD (address signal), a CMD (command signal), and a CLK (clock signal) are laid out with a conventional pitch (up to 80 micrometers).

To give an example, in a semiconductor memory with 64 DQ input/output terminals, the number of the PADs arranged with a narrow pitch is 120, and the number of the PADs arranged with a conventional pitch is 40. In this case, the narrow-pitched PADs include: 64 PADs for data input/output DQs (DQ0 to DQ63); two PADs for DQS associated with every eight data input/output DQs (16 in all); one PAD for a DM associated with every eight data input/output DQs (8 in all); and a plurality of PADs for power sources VDDQ and VSSQ. The PADs arranged with a conventional pitch include: 14 PADs for an address signal ADD; PADs for a plurality of clock signals CLK; and PADs for a plurality of command signals CMD.

By making the majority of the PADs of this semiconductor memory equal in pitch to the PADs of the processor chip, it becomes possible to directly connect the semiconductor memory with the processor chip without problems. However, it is difficult to probe the PADs arranged with a narrow pitch at the time of a shipment test. Therefore, in the present embodiment, the probe check at the time of a shipment test is conducted by use only of the PADs arranged with a conventional pitch. Consequently, in the present embodiment, to make the probe check at the time of a shipment test possible, there are newly provided: test-purpose VDDQ PADs 61 and 65, and test-purpose VSSQ PADs 64 and 68, the PADs being power source terminals arranged with a conventional pitch and allowing probing with a conventional positional accuracy; and four test-purpose input/output PADs (TEST1 to TEST4) (62, 63, 66, and 67) as data input/output terminals. They are dispersedly arranged, for example at edge portions of the chip as shown in FIG. 4.

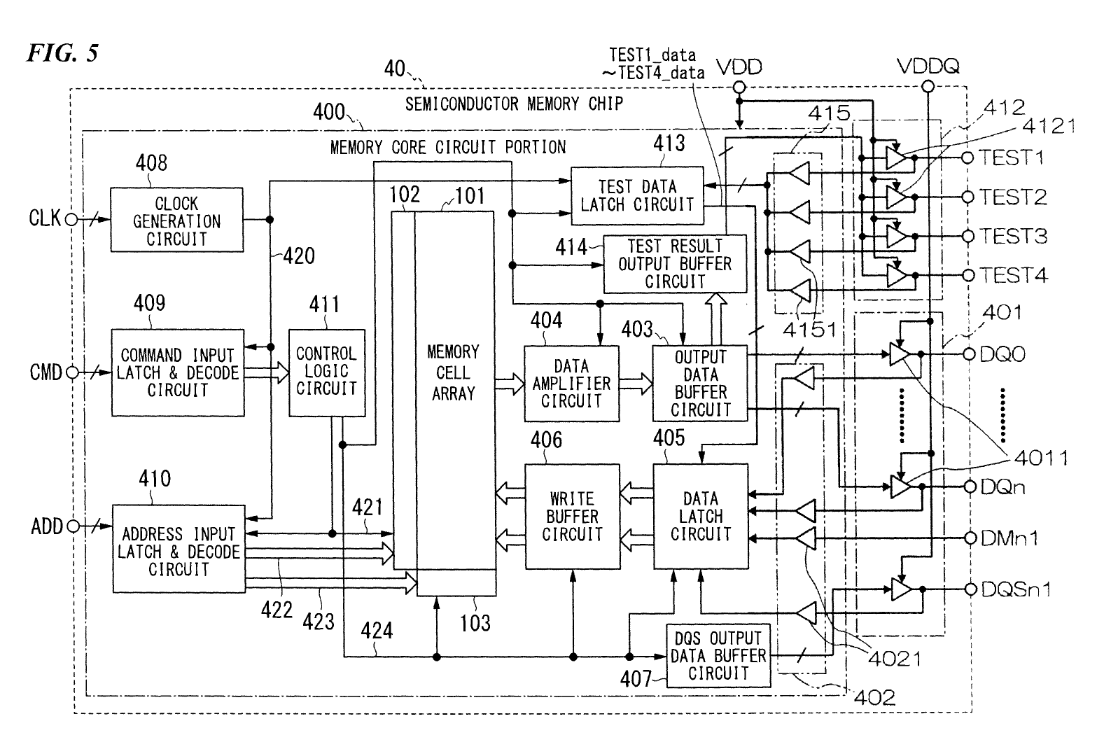

FIG. 5 shows a block diagram of the semiconductor memory (chip) 40 shown in FIG. 4. The semiconductor chip 40 includes: a memory core circuit portion 400; an output circuit portion 401; and a test output circuit portion 412 including four buffer circuits 4121. A VDD is a power source supplied to the memory core circuit portion 400 and the test output circuit portion 412. A VDDQ is a power source supplied to the output circuit portion 401. In a semiconductor memory, a power source VDD for operational use is usually separated from a power source VDDQ for a data output circuit. Especially in recent years, when a semiconductor memory is used in portable equipment with low power consumption, a VDDQ with a voltage level lower than a VDD is supplied, to thereby reduce consumption current of the system.

The memory core circuit portion 400 includes: a memory cell array 101 including a plurality of memory cells; a row decoder 102 and a column decoder 103 for selecting a predetermined memory cell within the memory cell array 101; an input circuit 402 including a plurality of buffer circuits 4021; an output data buffer circuit 403; a data amplifier circuit 404; a data latch circuit 405; a write buffer circuit 406; a DQS output data buffer circuit 407; a CLK (clock) generation circuit 408; a command input latch & decode circuit 409; an address input latch & decode circuit 410; a control logic circuit 411; a test data latch circuit 413; a test result output buffer circuit 414; and a test input circuit 415 including a plurality of buffer circuits 4151. Furthermore, the output circuit portion 401 includes a plurality of buffer circuits 4011.

In FIG. 5, configurations the same as those shown in FIG. 2 are denoted by the same reference symbols (hereinafter, the same applies to the respective figures). Furthermore, the input circuit 402, the output data buffer circuit 403, the data amplifier circuit 404, the data latch circuit 405, the write buffer circuit 406, the DQS output data buffer circuit 407, the CLK generation circuit 408, the command input latch & decode circuit 409, the address input latch & decode circuit 410, the control logic circuit 411, and the output circuit portion 401 of FIG. 5 respectively correspond to the input circuit 202, the output data buffer circuit 203, the data amplifier circuit 204, the data latch circuit 205, the write buffer circuit 206, the DQS output data buffer circuit 207, the CLK generation circuit 208, the command input latch & decode circuit 209, the address input latch & decode circuit 210, the control logic circuit 211, and the output circuit portion 201 of FIG. 2. As for the aforementioned basic functions relating to input/output of data, they offer the same functions.

In addition, an internal clock signal 420, a row control signal 421, a row address signal 422, a column address signal 423, and a column control signal 424 respectively correspond to the internal clock signal 220, the row control signal 221, the row address signal 222, the column address signal 223, and the column control signal 224 of FIG. 2.

For test-purpose input/outputs TEST1 to TEST4 shown in FIG. 5 (signals which are input/output via the PADs 62, 63, 66, 67 of FIG. 4), there is provided a test input circuit 415. Test input data which is input via the test input circuit 415 is latched in the test data latch circuit 413 in accordance with the internal clock signal 420 and is then sent to the data latch circuit 405 as TEST1_data to TEST4_data. Furthermore, the test output circuit portion 412 outputs the data which has been sent from the output data buffer circuit 403 to the test result output buffer circuit 414.

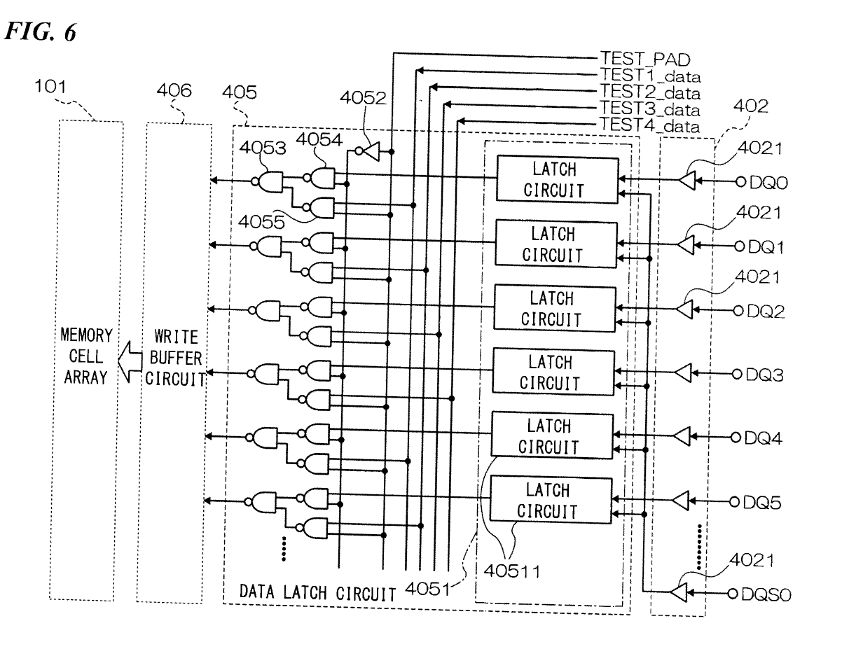

FIG. 6 shows a configuration of the data latch circuit 405 of FIG. 5. The data latch circuit 405 of FIG. 5 includes: a data latch portion 4051 including a plurality of latch circuits 40511 for latching a data input/output DQ synchronous with a CLK signal input/output DQS for data transmission/reception; and a selector portion including an inverter 4052 and plural sets of three NANDs 4053 to 4055. A test signal TEST_PAD is an output signal, of the control logic circuit 411, which is set to a high level when a predetermined command is input to the command input CMD. The pieces of the test data TEST1_data to TEST4_data which have been input from the TEST-purpose input/output PADs TEST1 to TEST4 (PADs 62, 63, 66, and 67) and latched in the test data latch circuit 413 are input to the data latch circuit 405. When an input of the predetermined command to the command input CMD causes the semiconductor memory 40 to enter a test mode, to thereby set the test signal TEST_PAD to a high level, the data latch circuit 405 disables inputs from the DQ terminals (DQ0, DQ1, . . . ), sends the pieces of the test data TEST1_data to TEST4_data, instead of data signals DQ0 to DQ3, DQ4 to DQ7, . . . , to the write buffer circuit 406 respectively as pieces of data of four successive DQs, and then writes them to the memory cell array 101.

The data latch circuit 405 selects, as data to be written to the memory cell, either the data which has been input from the data input/output DQ terminals or the data which has been input from the test-purpose input/output PADs. At that time, allocation (substitution) between the inputs from the DQ terminals (DQ0, DQ1, . . . ) and the pieces of the test data TEST1_data to TEST4_data is performed based on the array of the PADs on the semiconductor memory chip 40 shown in FIG. 4. For example, the pieces of the test data TEST1_data to TEST4_data are allocated to four adjacent PADs in the order of the arrangement thereof. Furthermore, the test-purpose input/output PADs are fewer than the DQ terminals (data input/output DQ PADs). Therefore, one TEST1_data is repetitively allocated to two or more DQs.

Note that in the data latch circuit 405 of FIG. 6, the selector portion including an inverter 4052 and plural sets of three NANDs 4053 to 4055 is provided on the write buffer circuit 406 side as a subsequent stage to the data latch portion 4051. As a result, in taking in the pieces of the test data TEST1_data to TEST4_data, no input of the CLK signal input/output DQS for data transmission/reception is necessary.

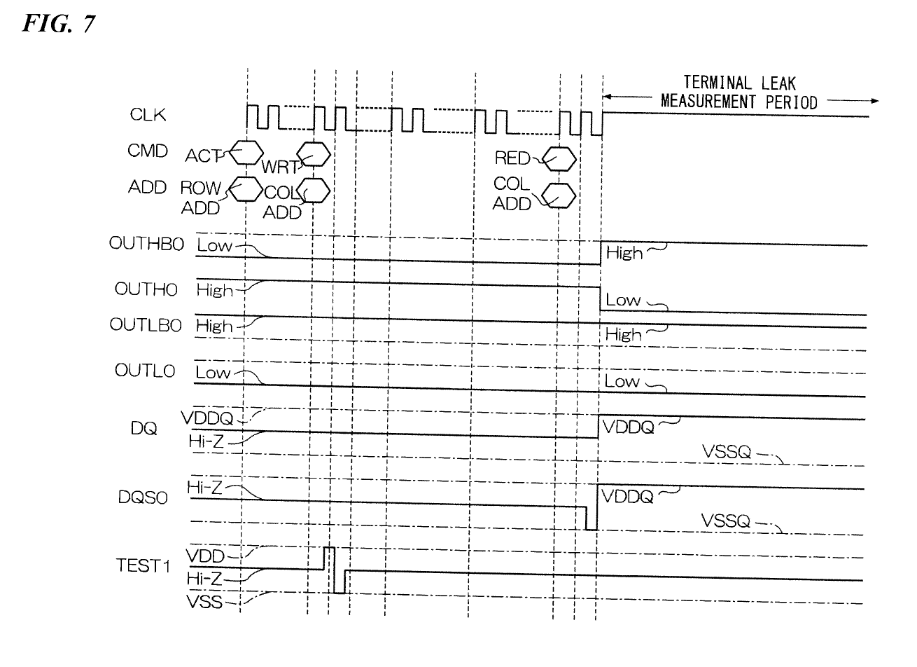

FIG. 7 shows a timing chart at the time of a leak test of the DQ and DQS terminals in the semiconductor memory 40 of the present embodiment. To conduct a leak test on the DQ and DQS terminals in the present embodiment, a predetermined command is input to the command input CMD to enter a test mode, to thereby set the test signal TEST_PAD to a high level. When the test signal TEST_PAD is set to a high level, it becomes possible, as described above, to disable the inputs from the DQ terminals, and to send the pieces of the data TEST1_data to TEST4_data which have been input from the test-purpose input/output PADs TEST1 to TEST4 (PADs 62, 63, 66, and 67 of FIG. 4) to the write buffer circuit 406 respectively as pieces of data of four successive DQs such as DQ0 to DQ3, DQ4 to DQ7, . . . , to thereby write them to the memory cell array 101.

In general, entry into a test mode is performed with a mode register command. Hereunder is a description of a leak test method in the present embodiment using the timing chart of FIG. 7.

First, with an active command (ACT), a row address line is selected to bring the row address line into an active state. Next, with a write command (WRT), data is written to a memory cell at a column address on the row address line. Note that the write data at this time is input from the test-purpose input/output PADs TEST1 to TEST4 (PADs 62, 63, 66, and 67 of FIG. 4).

FIG. 7 shows input waveforms of the test-purpose input/output PAD TEST1 (PAD 62). Writing is performed to two successive bits from a selected column address. This example shows a case where high data is written to the first bit of the column address. Subsequently, a read command (RED) is input to output the data which has been written to the memory cell with the write command (WRT) from the DQ terminals. Two cycles after the read command (RED), two successive bits from the selected column address are output synchronous with a rising edge and a falling edge of the CLK signal. In this test, a state where the CLK signal has risen is maintained to maintain a state where an output of the DQ is a high level. In the meantime, a leak test on DQ terminals is conducted during the period which is shown in FIG. 7 as “terminal leak measurement period”. That is, a leak test is conducted in the terminal leak measurement period, while the clock signal CLK is maintained a high level to continuously output the specific pieces of data which have been input at TEST1 to TEST4 from DQ0 to DQ3, DQ4 to 7, . . . .

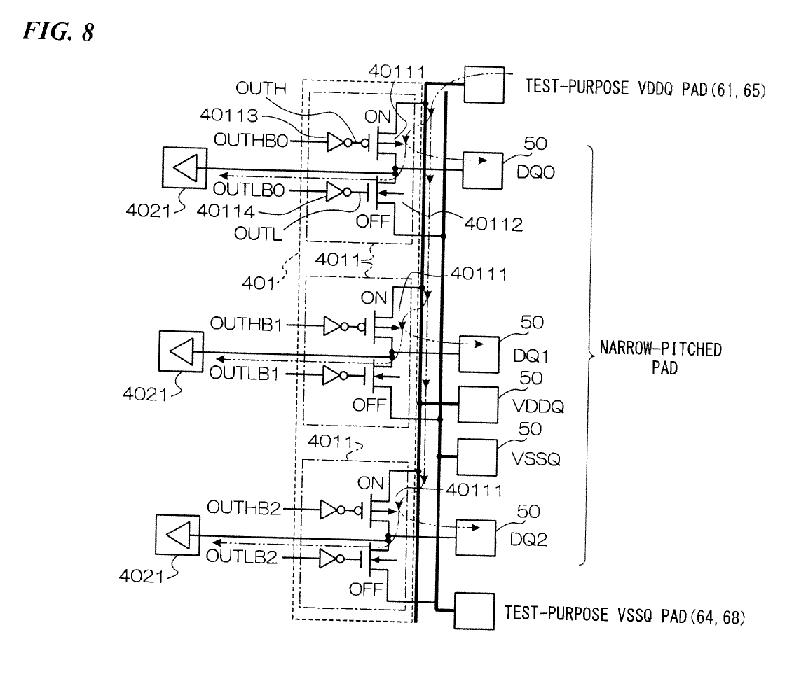

Note that in FIG. 7, signals OUTHB0, OUTH0, OUTLB0, and OUTL0 denote respective input signals and output signals of inverters 40113 and 40114 which are drivers for output transistors 40111 and 40112 in respective output buffer circuits 4011 of the DQ terminals shown in FIG. 8. In FIG. 7, the notation “Hi-Z” denotes a high impedance state.

FIG. 8 shows the condition of a DQ terminal output circuit in a leak test of the present embodiment. More particularly, FIG. 8 shows the configuration of a portion around the data input/output terminals DQ0, DQ1, and DQ2 (PADs 50 of FIG. 4) in the output circuit portion 401 and the input circuit 402 shown in FIG. 5. Each of the output buffers 4011 within the output circuit portion 401 includes: a P-channel MOS (Metal Oxide Semiconductor) transistor 40111; an N-channel MOS transistor 40112; and inverters 40113 and 40114. Furthermore, in the present embodiment, a test-purpose VDDQ PAD 61 or 65 (see FIG. 4) is connected with a power source VDDQ supplied to the output circuit portion 401. A test-purpose VSSQ PAD 64 or 68 is connected with a power source VSSQ supplied to the output circuit portion 401. As a result, electric power can be supplied to lines of the power sources VDDQ and VSSQ connected with narrow-pitched PADs 50 from the conventional-pitched test-purpose VDDQ PAD 61 or 65, and from the conventional-pitched test-purpose VSSQ PAD 64 or 68.

FIG. 8 shows an example of a case where all the three terminals of DQ0, DQ1, and DQ2 are caused to output high data, and at the same time it is checked whether or not a leakage path due to a defect or the like is present. The three terminals of DQ0, DQ1, and DQ2 are in the state of outputting high data. Therefore, for all three terminals, the P-channel MOS transistor 40111 is turned ON, and hence the respective DQ terminals are in conduction with the power source VDDQ. In this state, current over the paths shown by double-dot chain lines of FIG. 8 is measured at the test-purpose VDDQ PAD. Measurement of current is performed by measuring whether or not current is flowing between a probe needle probed in the test-purpose VDDQ PAD 61 or 65 and a probe needle probed in another conventional-pitched PAD. The VDDQ is a power source dedicated to the output circuits. Therefore, current does not flow unless a leakage path due to a defect or the like is present in the respective DQ terminals. With the presence of a leakage path, current is measured, revealing the product as defective.

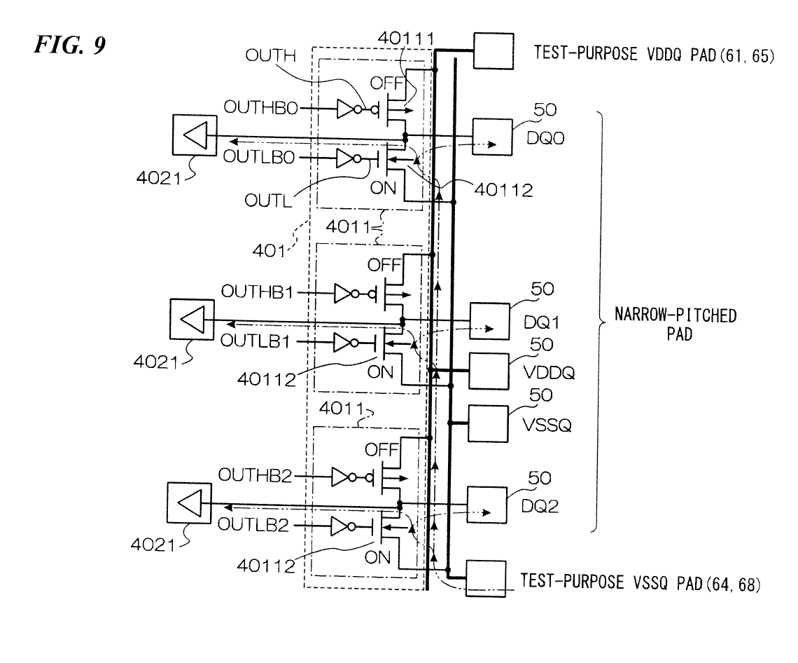

Another output state of a DQ terminal output circuit at the time of a leak test is shown in FIG. 9. FIG. 9 shows a case where all the three terminals of DQ0, DQ1, and DQ2 are caused to output low data, and the respective output N-channel MOS transistors 40112 are turned ON, to thereby measure current from the probe of the test-purpose VSSQ PAD 64 or 68. In accordance with the specifications of the semiconductor memory 40, the VSSQ of the output circuit portion 401 is separated from the VSS of the memory core circuit portion 400, and hence allows measurement in a similar manner as the VDDQ.

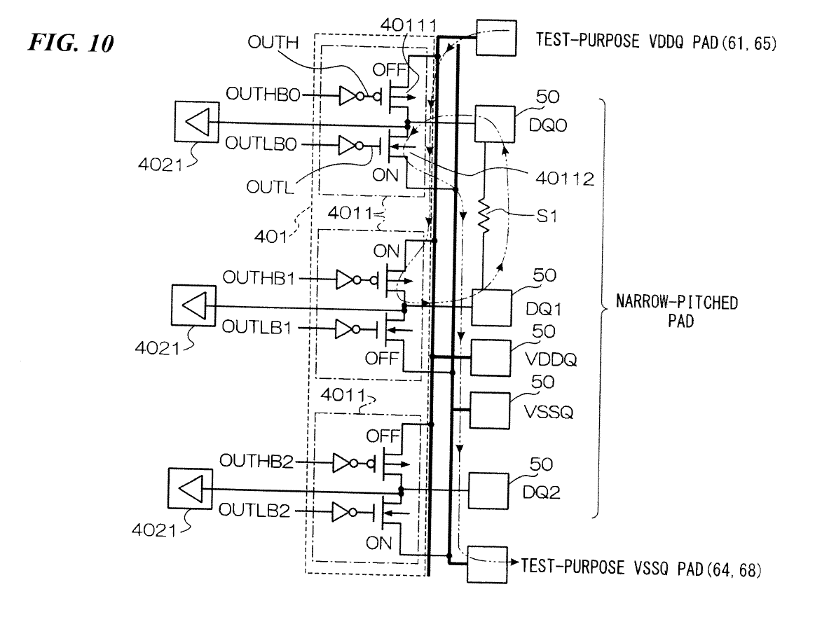

Still another state of a DQ terminal output circuit in a leak test is shown in FIG. 10. FIG. 10 shows a state of the DQ terminal output circuit in the case where a leak test is conducted between the adjacent PADs for the DQ1, with the DQ0 as low output, the DQ1 as high output, and the DQ2 as low output. In this state, when there is a short circuit S1 as shown in the figure, a leakage current is detected over the path shown by the double-dot chain line from the VDDQ (the test-purpose VDDQ PAD 61 or 65 and the test-purpose VSSQ PAD 64 or 68). To check a leakage path in this case, it is necessary to write data such as ‘0101’ or ‘1010’ to four adjacent DQs and read it. In the present embodiment, this is made possible by inputting the data of ‘0101’ or ‘1010’ from the TEST1 to TEST4 (the test-purpose input/output PAD1 to PAD4 (62, 63, 66, and 67)).

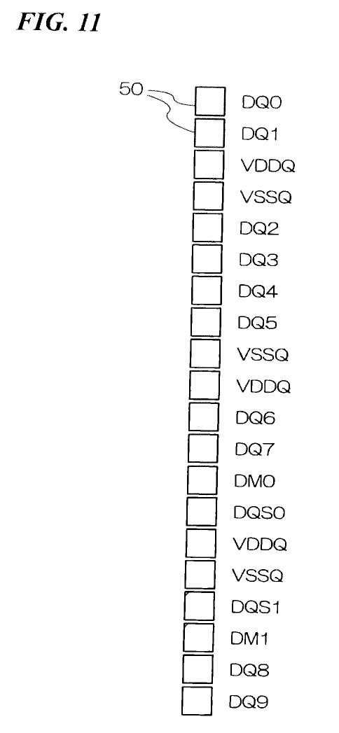

Next is a description of another embodiment of the present invention with reference to FIG. 11 to FIG. 16. FIG. 11 shows one example of a general PAD array of a semiconductor memory. In the description of the above embodiment, a leak test method at a site where data input/output DQ terminals are successively arranged has been shown. However, in an actual arrangement of DQ terminals, CLK signal DQS PADs for data transmission/reception and data mask signal DM PADs are often mixed to be arranged as shown in FIG. 11. Therefore, to conduct a leak test between adjacent PADs for all the DQ terminals, it is required that a leak test be conducted also on CLK signal DQS PADs for data transmission/reception and data mask signal DM PADs in a similar manner for the DQ terminals. That is, it is required that a leak test can be conducted using only conventional-pitched PADs (PADs 51 or PADs 61 to 68 of FIG. 4).

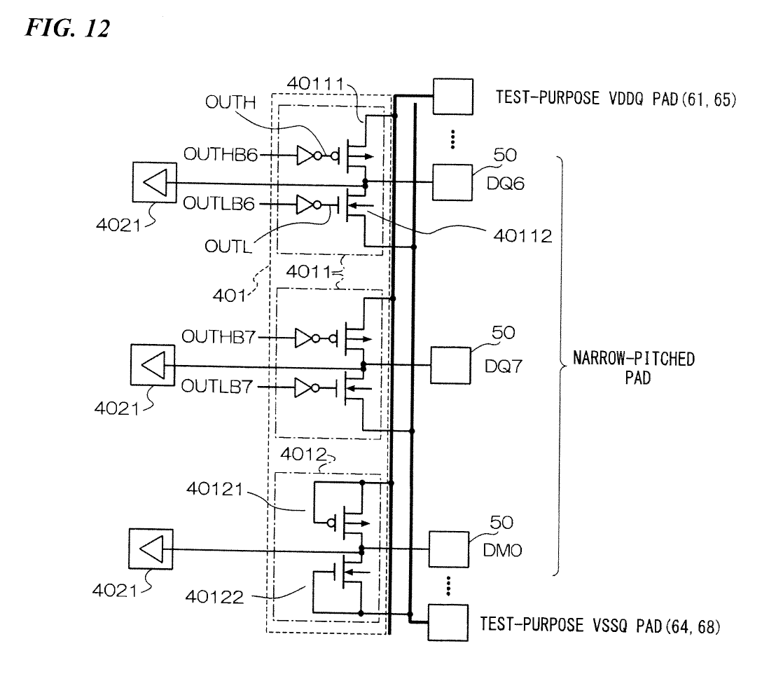

An input signal to the data mask signal DM terminal is input with the same timing as the DQ signal, and is latched by the CLK signal DQS for data transmission/reception. Therefore, a MOS transistor precisely identical to the output transistor of the DQ terminal is generally added to the data mask signal DM terminal for the purpose of terminal capacitance correction, in order to allow the input signal to the data mask signal DM terminal to be input with the same input timing as the DQ signal. FIG. 12 shows an example of a configuration of an output circuit of a data mask signal DM terminal conceivable in the case where a transistor circuit for terminal capacitance correction 4012 is added. In this case, the transistor circuit for terminal capacitance correction 4012 includes transistors 40121 and 40122, which are the identical to the output transistors 40111 and 40112 in the respective output buffer circuits 4011, the difference being that in the respective output transistors 40121 and 40122, the gate and the source are short circuited. Note that the data mask signal DM PAD is a terminal for data input. If a data mask signal DM to be input to this terminal is at a high level, the DQ signal is masked.

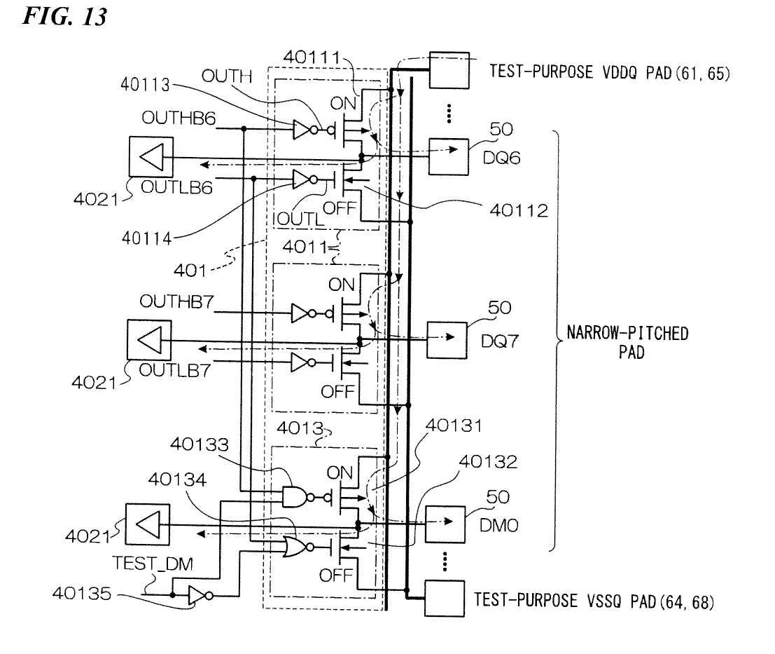

To conduct a leak test on a data mask signal DM terminal to which a transistor circuit for terminal capacitance correction 4012 is added, it is required that a MOS output transistor (40111 or 40112) on the target site for the leak test be turned ON to bring the measurement terminal into conduction with the VDDQ or the VSSQ, as described with reference to FIG. 8 or the like. Therefore, in the present embodiment, as shown in FIG. 13, the gate of the MOS transistor added for terminal capacitance correction is controlled in a similar manner for the further adjacent DQ (the further next DQ, or the further next DQ but one) by means of a test mode signal, to thereby allow the measurement terminal to be in conduction with the VDDQ or the VSSQ.

FIG. 13 shows a configuration of an output circuit of a data mask signal DM terminal in accordance with the present embodiment. More particularly, FIG. 13 shows a configuration of input/output circuits of data input/output terminals DQ6 and DQ7, and of a data mask signal terminal DM. Each output buffer circuit 4011 corresponding to a terminal DQ within an output circuit portion 401 includes: a P-channel MOS transistor 40111; an N-channel MOS transistor 40112; and inverters 40113 and 40114. Furthermore, an output circuit 4013 corresponding to a terminal DM includes: a P-channel MOS transistor 40131 and N-channel MOS transistor 40132 which are identical (at least equivalent in input capacitance) to the respective transistors within the output buffer 4011; a 2-input NAND 40133 whose output is connected to the gate of a P-channel MOS transistor 40131; and a 2-input NOR 40134 whose output is connected to the gate of an N-channel MOS transistor 40132. To one input of the NAND 40133 is input a test mode signal TEST_DM. To one input of the NOR 40134 is input an inverted version of the test mode signal TEST_DM, which has been inverted by an inverter 40135. In addition, to the other inputs of the NAND 40133 and the NOR 40134 are input an OUTHB6 and an OUTLB6, respectively. The OUTHB6 and the OUTLB6 are signals which determine levels of the respective gates of the P-channel MOS transistor 40111 and the N-channel MOS transistor 40112 in the output buffer circuit 4011 of the DQ6 terminal. The DQ6 terminal is a terminal next to a data mask signal terminal DM (DM0) but the adjacent terminal (DQ7).

By inputting the OUTHB6 and the OUTLB6 respectively to the other inputs of the NAND 40133 and the NOR 40134, in the case where the test mode signal TEST_DM is turned to a high level, the gates of the P-channel MOS transistor 40131 and the N-channel MOS transistor 40132 become equal in level to the gates of the P-channel MOS transistor 40111 and the N-channel MOS transistor 40112 of the output buffer 4011 of the DQ6 terminal, respectively. That is, in the case where the test mode signal TEST_DM is turned to a high level, the output buffer 4013 of the DM terminal becomes equal in output level to the output buffer 4011 of the DQ6 terminal.

With this configuration, when the test mode signal TEST_DM is set to a high level through the input of a predetermined signal to the command input CMD, the signal level of the output data signals OUTHB6 and OUTLB6 of the DQ6 are given to the gates of the transistors for terminal capacitance correction (40131 and 40132) which are added for DM0. As a result, the transistors for terminal capacitance correction output the data identical to that of DQ6 from the DM terminal. Note that FIG. 13 shows a case where all the DQ6, DQ7, and DM0 terminals are caused to output high data to simultaneously check for the presence of a leakage path due to a defect or the like.

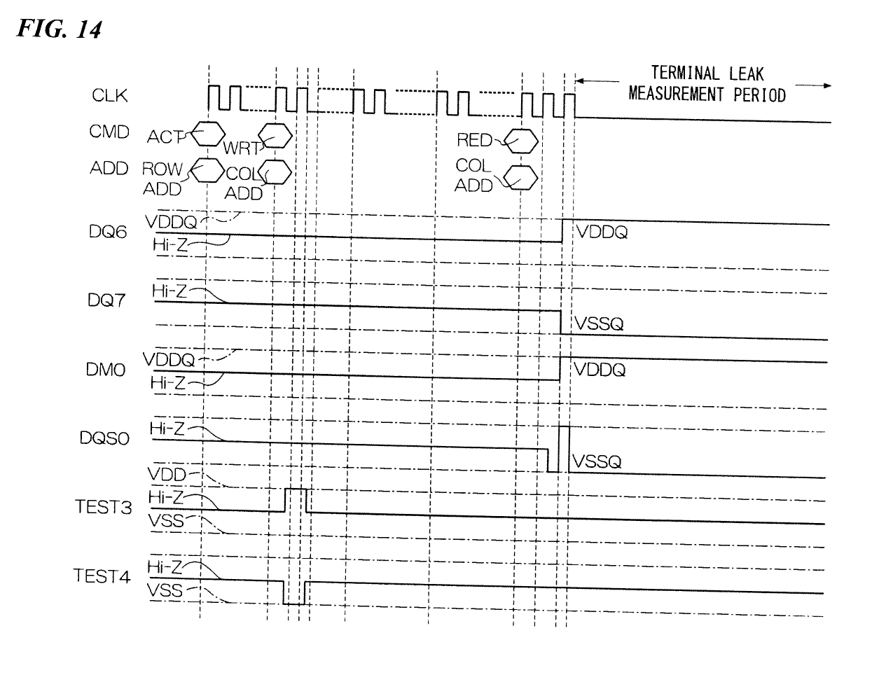

FIG. 14 shows a timing chart in the case where the respective terminals are caused to output the data of ‘1010’ to check for a leakage path between the adjacent PADs in the PAD array arranged in the order of the DQ6, the DQ7, the DM0, and DQS0 as shown in FIG. 11. In this case, the data latch circuit 405 (see FIG. 6) is configured such that the data having been input to the terminals TEST3 and TEST4 are written to the DQ6 and the DQ7, respectively. In addition, it is necessary to output ‘0’ (that is, a low level) from the DQS0. Therefore, during the terminal leak measurement period in the figure, the clock signal CLK is maintained at a low level, to thereby maintain the CLK signal input/output DQS0 for data transmission/reception in a fallen state. In this state, a leak test is conducted on the DQ, DQS, and DM terminals in a period shown as “terminal leak measurement period”.

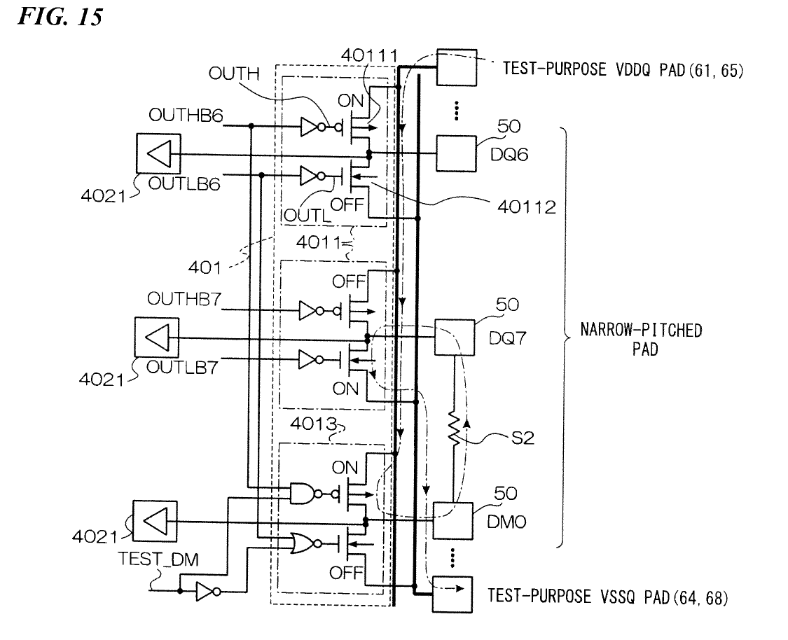

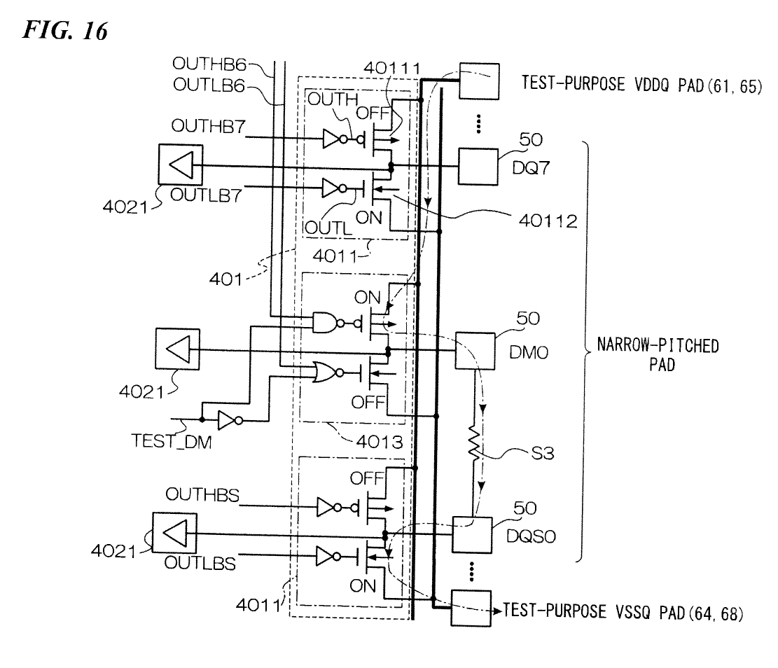

Since high data is written to the DQ6, the high data is output from the DQ6 and the DM0, and thereby a leak test between the desired adjacent PADs is conducted. FIG. 15 and FIG. 16 show a state of an output circuit at the time of this test. On short circuited sites S2 and S3 in the figures, a detection of a leakage path is performed along the paths shown by the double-dot chain lines.

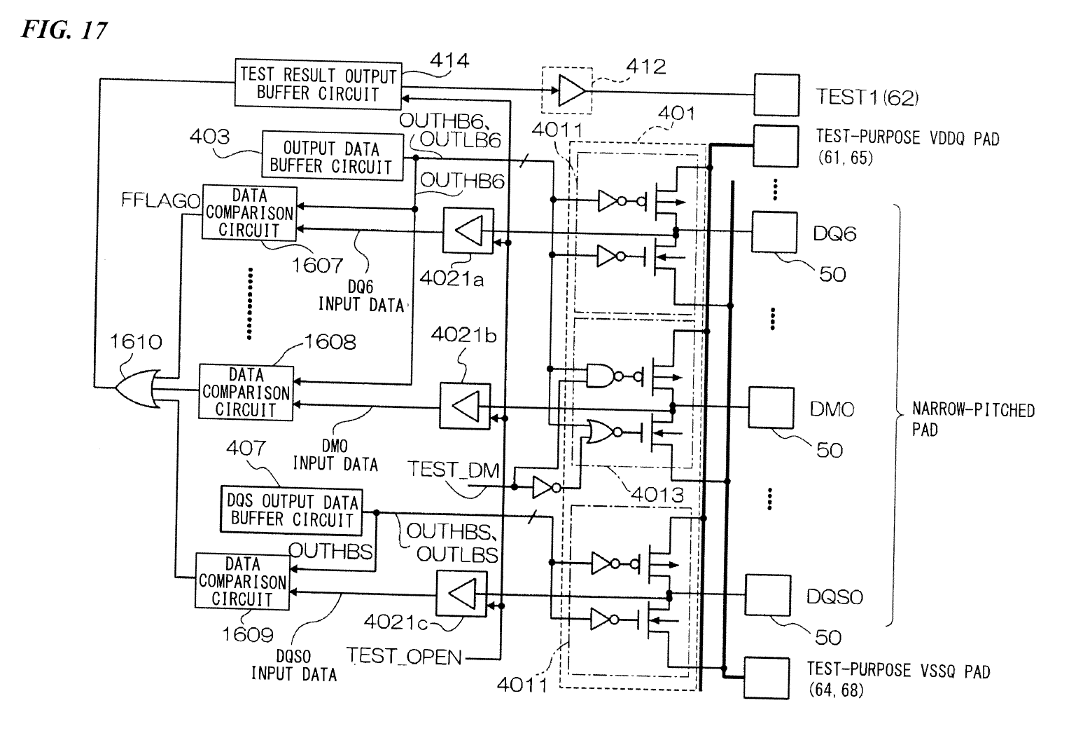

Next is a description of a circuit configuration which allows an operation check test (a check test on data input/output operations) of input/output circuits of DQ, DQS, and DM terminals, with reference to FIG. 17. Comparison with the configuration described with reference to FIG. 5 reveals that newly added components in FIG. 7 are data comparison circuits 1607 to 1609 and an OR circuit 1610. An output data signal OUTHB6 of an output data buffer circuit 403, and respective outputs of input circuits 4021a and 4021b of the DQ6 terminal and the DM0 terminal are input to the data comparison circuits 1607 and 1608 of the DQ6 and DM0, where the data to be output and the data which has been output are compared. Note that the input circuits 4021a to 4021c correspond to the buffer circuits 4021 of FIG. 5.

An output data signal OUTHBS of a DQS output data buffer circuit 407, and an output of input circuit 4021c of a DQS terminal are input to a data comparison circuit 1609 of DQS0, where a similar comparison is made. These comparisons allow checks for normal operations of the input/output circuits such as an output circuit portion 401 and an input circuit 402.

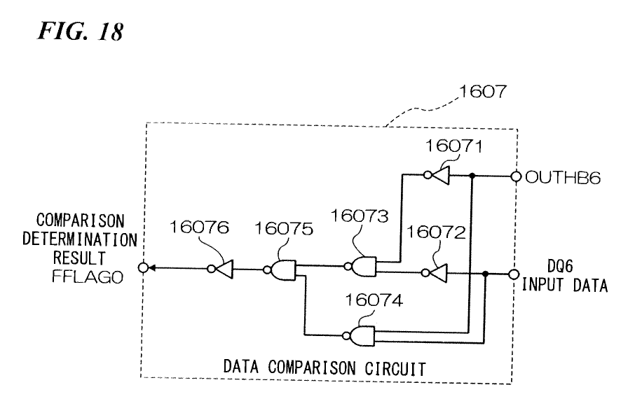

Here, one example of the data comparison circuit 1607 will be described with reference to FIG. 18. The data comparison circuit 1607 shown in FIG. 18 includes: an inverter 16071 which takes an output data signal OUTHB6 of an output data buffer circuit 403 as an input; an inverter 16072 which takes an output of input circuit 4021a of the DQ6 terminal as an input; a NAND 16073 which takes outputs of the inverter 16071 and the inverter 16072 as inputs; a NAND 16074 which takes the OUTHB6 and DQ6 input data as inputs; a NAND 16075 which takes outputs of the NAND 16073 and the NAND 16074 as inputs; and an inverter 16076 for inverting an output of the NAND 16075. An output FFLAG0 of the inverter 16076 shows a comparison result between the OUTHB6 and the DQ6 input data. If the comparison results in a mismatch, the comparison determination result FFLAG0 is turned to a high level.

The data comparison circuit 1608 for comparing the data mask signal DM0 with the signal OUTHB6 can be configured in the same manner as the data comparison circuit 1607 of FIG. 18. The data comparison circuit 1609 for comparing the output data signal OUTHBS of the DQS output data buffer circuit 407 with the output of the input circuit 4021c of the DQS terminal can also be configured in the same manner as the data comparison circuit 1607 of FIG. 18.

The OR circuit 1610 of FIG. 17 collects (combines) the comparison results of the respective terminals. It transmits a high output to a test result output buffer circuit 414 if even one mismatch is found in the comparison results. The mismatch signal is buffered in the test result output buffer circuit 414, and then is output via the test output circuit portion 412 to the test-dedicated input/output TEST1 (PAD 62 of FIG. 4). In a probe test, this TEST1 PAD output is read to conduct an operation check test on the input/output circuits of the DQ, DQS, and DM terminals.

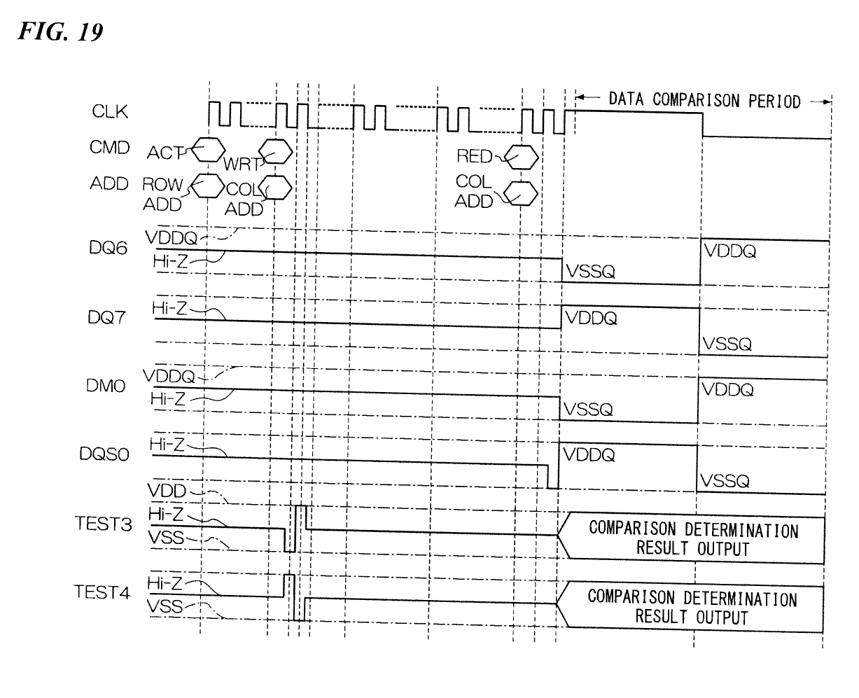

FIG. 19 shows a timing chart of the present embodiment shown in FIG. 17. Operations up to writing data from the test-dedicated input/output PADs (TEST1 PAD 62, TEST2 PAD 63, TEST3 PAD 66, and TEST4 PAD 67 of FIG. 4) to the memory cells, and reading and outputting the data are the same as the one at the time of a leak test. Difference from the leak test lies in the operations during the time when the data which has been output from the DQs and the DQSs is taken in by the DQ and DQS input circuits 4021a to 4021c, and the data read from the memory cell is compared with output expectation data of the DQS (control level of the output transistors) in the data comparison circuits 1607 to 1609 to determine whether the two sets of data is matched or mismatched. That is, after the data is read from the memory cells, the CLK signal is kept in a high state or a low state for a predetermined time, during which the comparison is made. In this timing chart, the output data which is output synchronous with the rising edge of the CLK signal is made different from the output data which is output synchronous with the falling edge of the CLK signal, to thereby separately conduct an operation check test on an input/output of high data and an input/output of low data.

As described above, in the embodiments of the present invention, the semiconductor memory 40 is provided with test-dedicated input/output PADs, a test-dedicated VDDQ PAD, and a test-dedicated VSSQ PAD. At the time of a probe test, probing is performed for the test-dedicated input/output PADs without probing the VDDQ, VSSQ, DQ, and DQS PADs which are generally used in package assembly. Thereby, it is possible to conduct a leak test on the DQ and DQS terminals by measuring current of the test-dedicated VDDQ PAD or the test-dedicated VSSQ PAD while data which has been written to memory cells and then read from the memory cells is output from the DQ terminals.

Furthermore, data is written to the memory cells from the test-dedicated input/output PAD, and the data is read and output. Then, the data which has been output from the DQs and the DQSs is taken in by the DQ and DQS input circuits. Subsequently, the data comparison circuit determines whether the data read from the memory cells and the output expectation data of the DQS are matched or mismatched. As a result, it is possible to conduct an operation check test on the input/output circuits of the DQ and DQS terminals without probing in the DQ and DQS terminals.

Furthermore, a transistor for input capacitance correction added to the DM terminal is controlled in a test mode in a similar manner for output transistors of the DQ terminals, to thereby make it possible to conduct a leak test and an operation check test on the input/output circuits in a similar manner for the DQ terminals.

The semiconductor memory of the present invention is provided with test-dedicated input/output PADs, a test-dedicated VDDQ PAD, and a test-dedicated VSSQ PAD, to thereby be capable of conducting a leak test and of checking operations of the input/output circuits without probing in the DQs, DQS, and DM PADs. As a result, a PAD pitch of the DQ, DQS, and DM PADs can be modified to a narrow pitch, which is necessary when a semiconductor memory is stacked with a processor chip. Furthermore, this allows areas occupied by the PADs to be smaller. Therefore, an overhead of a chip size can be suppressed, leading to reduction in chip cost.

Embodiments of the present invention are not limited to the above. For example, modifications are appropriately possible such as increase in number of conventional-pitched test-purpose PADs or in number of pieces of internal test data, increase or decrease in the number of the PADs of test-purpose power sources, and a change in arrangement of the PADs.

What is claimed is:

1. A semiconductor device comprising, on a single semiconductor chip:
a memory circuit;
a group of terminals each provided to perform communication between the memory circuit and an outside of the single semiconductor chip, the group of the terminals including first and second terminals that are arranged adjacently to each other with a first interval therebetween;
a test terminal provided to perform communication between the memory circuit and the outside of the single semiconductor chip and arranged adjacently to a terminal of the group of terminals, which is positioned at the end of an arrangement of the group of terminals, with a second interval therebetween, the second interval being larger than the first interval; and
a selector coupled to the first and second terminals, the test terminal and the memory circuit, the selector making, in a test operation mode, a first electrical path between the test terminal and the memory circuit while electrically disconnecting each of the first and second terminals from the memory circuit and making, in a normal operation mode, a second electrical path between the first terminal and the memory circuit and a third electrical path between the second terminal and the memory circuit while electrically disconnecting the test terminal from the memory circuit.

2. The device as claimed in claim 1, wherein the test terminal is a first test terminal and the memory device comprises a second test terminal provided to perform communication between the memory circuit and the outside of the single semiconductor chip and arranged adjacently to the first test terminal with an interval that is substantially equal to the second interval, the group of terminals further includes third and fourth terminals arranged adjacently to each other with an interval that is substantially equal to the first interval, the selector being further coupled to the second test terminal and third and fourth terminals to make, in the test operation mode, a fourth electrical path between the second test terminal and the memory circuit while electrically disconnecting each of the third and fourth terminals from the memory circuit and make, in the normal operation mode, a fifth electrical path between third terminal and the memory circuit and a sixth electrical path between the fourth terminal and the memory circuit while electrically disconnecting the second test terminal from the memory circuit.

3. The device as claimed in claim 1, the group of terminals further includes a fifth terminal that is electrically connected to the memory circuit in both of the test operation mode and the normal operation mode.

4. The device as claimed in claim 3, wherein the fifth terminal is arranged adjacently to one or ones of the group of terminals with an interval that is substantially equal to the second interval.

5. A semiconductor device comprising, on a single semiconductor chip:
a memory circuit;
a plurality of first terminals provided to perform communication between the memory circuit and an outside of the single semiconductor chip, the plurality of first terminals being arranged in line with a substantially equal first interval to one another; and
a plurality of second terminals provided to perform communication between the memory circuit and the outside of the single semiconductor chip, the plurality of second terminals being arranged in line with a substantially equal second interval to one another, the second interval being different from the first interval.

6. The device as claimed in claim 5, wherein the second interval is larger than the first interval.

7. The device as claimed in claim 6, wherein the single semiconductor chip has first and second sides opposite to each other, the plurality of first terminals being arranged along the first side of the single semiconductor chip and the plurality of second terminals being arranged along the first side of the single semiconductor chip.

8. The device as claimed in claim 7, wherein the plurality of first terminals and the plurality of second terminals are arranged in line, and a distance between an arrangement of the first terminals and an arrangement of the second terminals being larger than the first interval.

9. The device as claimed in claim 8, the distance is substantially equal to the second distance.

10. The device as claimed in claim 5, wherein the plurality of first terminals includes one or more input/output terminals and does not include any input terminal, and the plurality of second terminals includes one or more input terminals and does not include any input/output terminal.

11. The device as claimed in claim 10, further comprising one or more output circuits each outputting data to a corresponding one of the input/output terminals, wherein the plurality of first terminals further includes one or more power source terminals which supplies voltages to the output circuits, respectively.

12. The device as claimed in claim 11, wherein the plurality of first terminals further includes one or more data strobe terminals and one or more data mask terminals.
